(19) United States
(12) Patent Application Publication
(10) Pub. No.: US 2026/0213645 A1
(43) Pub. Date: Jul. 23, 2026

(54) ELECTRICAL POWER CONDITIONING UNIT

(71) Applicant: Intergalactic Spaceworx, LLC, St. George, UT (US)

(72) Inventor: Matthew Hansen, St. George, UT (US)

(21) Appl. No.: 19/451,208

(22) Filed: Jan. 16, 2026

Related U.S. Application Data
(60) Provisional application No. 63/746,605, filed on Jan. 17, 2025.

(51) Int. Cl. H02M 1/14; H02M 1/00; H02M 3/157; H03K 7/08

(52) U.S. Cl. CPC H02M 1/143; H02M 1/0019; H02M 1/0022; H02M 3/157; H03K 7/08

(57) ABSTRACT

A method of conditioning electrical power includes applying, by a voltage sampler, a voltage feedforward term to accommodate a voltage ripple or a steady state voltage generated by a voltage source. The method additionally includes applying, by a feedforward controller, a current feedforward component to a boost converter or other power converter, the current feedforward component forces the boost converter7 to absorb a load current ripple produced by a load and prevent the load current ripple from passing onto the voltage source/busbar. The method also includes regulating, by a PID controller, an output voltage to match the reference voltage by modulating a PWM signal.

### CROSS-REFERENCE TO RELATED APPLICATION(S)

This application claims priority to and the benefit of U.S. Provisional Patent. No. 63/746,605, filed Jan. 17, 2025, the entirety of which is incorporated herein by reference.

### FIELD

This disclosure relates generally to an electrical power conditioning unit, and more particularly relates to a power conditioning unit.

### BACKGROUND

Typically, a power conditioning unit in a power distribution system uses a passive filter to provide clean voltage going from the voltage source to a load (attenuating voltage ripples downstream above some corner frequency) and to provide a clean current going to a busbar or a voltage source from the load (attenuating current ripples on the busbar above the same corner frequency). However, a passive filter requires damping and extra capacitance, which can lead to increased power loss. Moreover, the extra capacitors commonly associated with passive filters makes the power conditioning unit heavier and bulkier.

### SUMMARY

A power conditioning unit is disclosed for supplying a clean voltage going to a load from a voltage source and a clean current going from the load to the voltage source. The power conditioning unit includes a boost converter which includes an inductor, a first transistor, a second transistor, and a capacitor. The first transistor is turned on, based on a first pulse width modulation (“PWM”) signal generated by a PWM driver, to accumulate current through the inductor. The second transistor is turned on, based on a second PWM signal, to direct the current, accumulated by the inductor, onto a load downstream from the inductor and the capacitor is configured to absorb a load current ripple produced by the load and a switching action. The power conditioning unit includes a voltage sampler configured to apply a voltage feedforward component to accommodate a voltage ripple or a steady state voltage generated by a voltage source. The power conditioning unit includes a feedforward controller configured to apply a current feedforward component to counteract the load current ripple absorbed by the capacitor of the boost converter and prevent the current ripple from flowing onto the bus. The power conditioning unit includes a proportional-integral-derivative (“PID”) controller configured to regulate output voltage to match a reference voltage by modulating the first PWM signal.

A method performed by a power conditioning unit, the method includes applying, by a voltage sampler, a voltage feedforward term to accommodate a voltage ripple or a steady state voltage generated by a voltage source. The method includes applying, by a feedforward controller, a current feedforward component to a boost converter, the current feedforward component counteracts a load current ripple produced by a load and absorbed by a capacitor of the boost converter. The method includes regulating, by a PID controller, an output voltage to match the reference voltage by modulating a PWM signal.

### BRIEF DESCRIPTION OF THE DRAWINGS

In order that the advantages of aspects of the disclosure will be readily understood, a more particular description of the aspects of the disclosure briefly described above will be rendered by reference to specific aspects of the disclosure that are illustrated in the appended drawings. Understanding that these drawings depict only typical aspects of the disclosure and are not therefore to be considered to be limiting of its scope, aspects of the disclosure will be described and explained with additional specificity and detail through the use of the accompanying drawings, in which:

FIG. 1 is a schematic block diagram illustrating a distribution system, according to various aspects of the disclosure;

FIG. 2 is a schematic block diagram illustrating another distribution system, according to various aspects of the disclosure;

FIG. 3 is a circuit diagram of a boost converter, according to various aspects of the disclosure;

FIG. 4 is a schematic block diagram illustrating another distribution system including a buck converter, according to various aspects of the disclosure;

FIG. 5 is a circuit diagram of the buck converter of FIG. 4, according to various aspects of the disclosure;

FIG. 6 is a schematic flow chart diagram illustrating a method performed by a power conditioning unit, according to various aspects of the disclosure; and

FIG. 7 is a schematic flow chart diagram illustrating another method performed by a power conditioning unit, according to various aspects of the disclosure.

### DETAILED DESCRIPTION

Reference throughout this specification to “one embodiment,” “an embodiment,” or similar language means that a particular feature, structure, or characteristic described in connection with the aspect of the disclosure is included in at least one aspect of the disclosure Thus, appearances of the phrases “in one embodiment,” “in an embodiment,” and similar language throughout this specification may, but do not necessarily, all refer to the same aspects, but mean “one or more but not all aspects of the disclosure” unless expressly specified otherwise. The terms “including,” “comprising,” “having,” and variations thereof mean “including but not limited to” unless expressly specified otherwise. An enumerated listing of items does not imply that any or all of the items are mutually exclusive or mutually inclusive, unless expressly specified otherwise. The terms “a,” “an,” and “the” also refer to “one or more” unless expressly specified otherwise.

Furthermore, the described features, structures, or characteristics of the disclosure can be combined in any suitable manner in one or more aspects of the disclosure. In the following description, numerous specific details are provided, such as examples of programming, software modules, user selections, network transactions, database queries, database structures, hardware modules, hardware circuits, hardware chips, etc., to provide a thorough understanding of aspects of the disclosure. One skilled in the relevant art will recognize, however, that the aspects of the disclosure can be practiced without one or more of the specific details, or with other methods, components, materials, and so forth. In other instances, well-known structures, materials, or operations are not shown or described in detail to avoid obscuring aspects of the disclosure.

The schematic flow chart diagrams included herein are generally set forth as logical flow chart diagrams. As such, the depicted order and labeled steps are indicative of one aspect of the disclosure of the presented method. Other steps and methods can be conceived that are equivalent in function, logic, or effect to one or more steps, or portions thereof, of the illustrated method. Additionally, the format and symbols employed are provided to explain the logical steps of the method and are understood not to limit the scope of the method. Although various arrow types and line types may be employed in the flow chart diagrams, they are understood not to limit the scope of the corresponding method. Indeed, some arrows or other connectors may be used to indicate only the logical flow of the method. For instance, an arrow may indicate a waiting or monitoring period of unspecified duration between enumerated steps of the depicted method. Additionally, the order in which a particular method occurs may or may not strictly adhere to the order of the corresponding steps shown.

Unless otherwise indicated, the terms “first,” “second,” etc. are used herein merely as labels, and are not intended to impose ordinal, positional, or hierarchical requirements on the items to which these terms refer. Moreover, reference to, e.g., a “second” item does not require or preclude the existence of, e.g., a “first” or lower-numbered item, or, e.g., a “third” or higher-numbered item.

As used herein, a system, apparatus, structure, article, element, component, or hardware “configured to” perform a specified function is indeed capable of performing the specified function without any alteration, rather than merely having potential to perform the specified function after further modification. In other words, the system, apparatus, structure, article, element, component, or hardware “configured to” perform a specified function is specifically selected, created, implemented, utilized, programmed, or designed for the purpose of performing the specified function. As used herein, “configured to” denotes existing characteristics of a system, apparatus, structure, article, element, component, or hardware which enable the system, apparatus, structure, article, element, component, or hardware to perform the specified function without further modification. For purposes of this disclosure, a system, apparatus, structure, article, element, component, or hardware described as being “configured to” perform a particular function can additionally or alternatively be described as being “adapted to” or as being “operative to” perform that function.

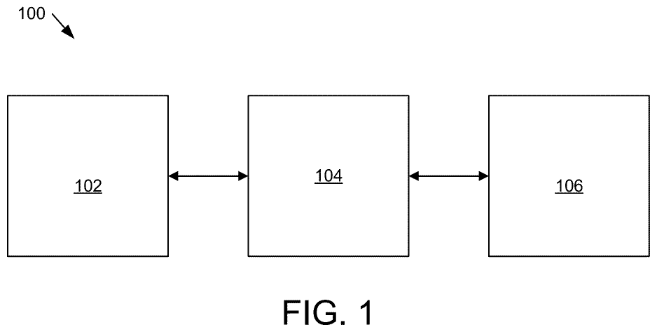

FIG. 1 is a schematic block diagram illustrating a power distribution system 100, according to various aspects of the disclosure. The power distribution system 100 includes a busbar 102, a power conditioning unit 104, and a load 106, which are described below.

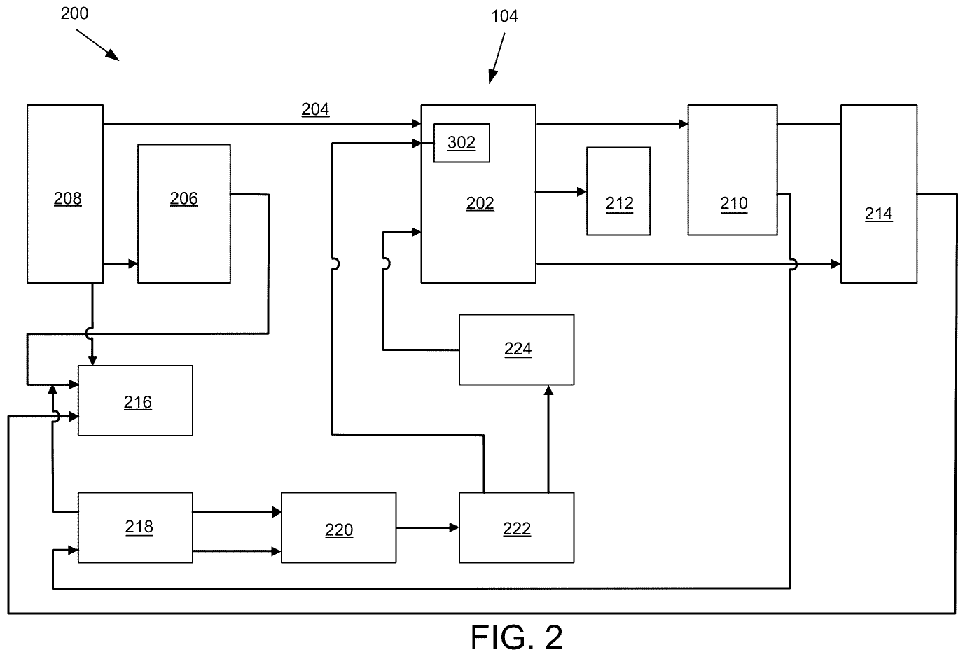

Unlike some conventional systems, the power conditioning unit 104 of the power distribution system 100 includes a boost converter (see FIG. 2) instead of a passive filter, which is further discussed in FIG. 2. The power conditioning unit 104 including a boost converter can be a boost converter or any other type of power converter, such as a Buck converter in a non-limiting example. In various aspects of the disclosure, such a boost converter is configured to minimize current ripple going to the busbar 102 from the load 106 (e.g., a downstream load). For example, the boost converter can be a type of converter designed to boost an input voltage through a controlled switching of a field effect transistor (“FET”), which alternates between ON and OFF states. This active switching allows the boost converter to regulate energy transfer efficiently. The active switching can be configured to attenuate shunt current ripple away from the busbar. The active switching is controlled using techniques like PWM or other known techniques, which adjusts the switch's duty cycle to more precisely regulate the given state. In some aspects of the disclosure, the boost converter can help to reduce the weight of the power conditioning unit 104 and to reduce power losses in the power distribution system 100.

The busbar 102 of the power distribution system 100 is used to conduct electricity within the power distribution system 100. In general, a busbar (e.g., the busbar 102) is a metallic strip or bar, typically housed inside busway enclosures for local high current power distribution. In general, busbars are used in high-voltage equipment, low-voltage battery applications, electrical control panels, or the like, to conduct, supply, or deliver current, voltage, power, or electricity. In this application, busbar can refer to any device that conducts electricity to supply power to the power conditioning unit, whether that device uses a busbar, wires, or any other similar electrically conductive technology or medium.

The load 106 of the power distribution system 100 consumes power generated by or provided from a voltage source (e.g., the voltage source 208 of FIG. 2). In some aspects of the disclosure, the load 106 can be, for example, one or more motors that drive compressors, pumps, fans, propulsion devices, etc. In various aspects of the disclosure, a load may not tolerate a voltage ripple produced by a voltage source, or may not be capable of tolerating a particular voltage ripple. For example, excessive voltage ripples can have negative or deleterious thermal, lifecycle, or control effects on such a load, such as excessive temperatures, varying motor torque to prematurely age the motor, having a poor response to the voltage ripples, such as amplifying the ripple or destabilizing the downstream controller. In some aspects of the disclosure, the load 106 produces a current ripple at one or more frequencies. In various aspects of the disclosure, the load 106 is located in a downstream relationship or section of the power distribution system 100.

FIG. 2 is a circuit illustrating another example of a power distribution system 200, according to various aspects of the disclosure, which can include or be integrated with the power distribution system 100 of FIG. 1. The power distribution system 200 includes a boost converter 202, a busbar 204, a voltage reference setter 206, a voltage source 208, a load current sampler 210 (i.e., current sampler), a load 212, a voltage divider 214, a PID controller 216, a feedforward controller 218, an adder 220, a current limiter 222, and a PWM driver 224. The boost converter 202 of the power distribution system 200 can be a power converter, for example, and can include an inductor 302. In some aspects of the disclosure, the boost converter 202 is electrically connected to the voltage source 208 via the busbar 204.

In some aspects of the disclosure, the power distribution system 200 includes a buck converter or another power converter instead of the boost converter 202. In general, a buck converter is referred to as a step-down converter that converts a relatively higher or larger first input voltage to a relatively lower or smaller second output voltage; other power converters can have different functionality. One skilled in the relevant art can modify various equations and formulae to adapt them to different power converters.

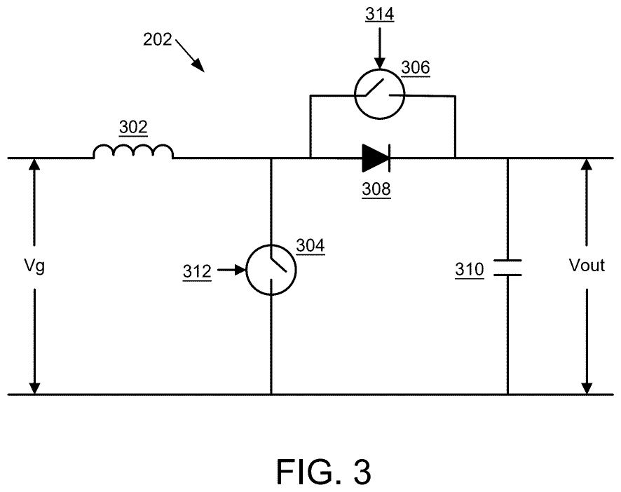

Referring to FIG. 3, the boost converter 202 is depicted with a first transistor 304, a second transistor 306, a diode 308, and a capacitor 310, or a combination thereof. In some aspects of the disclosure, the first transistor 304 is turned on or otherwise controllably operated, based on a first PWM signal 312, which can be generated by the PWM driver 224 of the power distribution system 200 of FIG. 2, for example, to accumulate by, or conduct current through, the inductor 302. In some aspects of the disclosure, the second transistor 306 is turned on or otherwise controllably operated, based on a second PWM signal 314, to deliver, supply, decrease, or otherwise conduct the current, accumulated by, or conducted through, the inductor 302, such as to the load 212 (FIG. 2), downstream from the inductor 302. In some aspects of the disclosure, the second PWM signal 314 is a complement of the first PWM signal 312, including deadtime and shoot-through protection. In some aspects of the disclosure, the capacitor 310 is configured to absorb, balance, even, or otherwise reduce a load current ripple produced by the conduction of current to the load 212 (FIG. 2).

In some aspects of the disclosure, the boost converter 202 is configured to boost an input voltage Vg supplied by the voltage source 208 (FIG. 2) to a different, higher or larger voltage. In some aspects of the disclosure, the boosting of the input voltage Vg at the boost converter 202 is kept at minimum to minimize the current ripple introduced back onto the busbar 204 (FIG. 2) or the voltage source 208 (FIG. 2).

Referring again to FIG. 2, the voltage reference setter 206 of the power distribution system 200 is configured to apply a voltage feedforward component to accommodate, represent, or account for a voltage ripple or a steady state voltage generated by the voltage source 208. In some aspects of the disclosure the voltage feedforward component can refer to a voltage feedforward term, a voltage feedforward signal, or a voltage feedforward value in non-limiting examples. In general, a feedforward device is an element or pathway within an electrical control system that passes a signal, such as a controlling signal, from a source in its external environment to a destination elsewhere in its external environment. Typically, a feedforward controller (e.g., feedforward controller 218) detects disturbances affecting the electrical control system and responsively supplies an additional input or signal (e.g., feedforward component or term) to minimize the effect of the disturbances. In a non-limiting example, the feedforward controller 218 can be a current cancellation controller or a transient cancellation component configured to mitigate current or voltage ripples or harmonics along the current or voltage supply.

In some aspects of the disclosure, applying the voltage feedforward component includes sampling, detecting, sensing, measuring, or estimating an input voltage to dynamically set the reference voltage. In some aspects of the disclosure, the voltage reference setter 206 is configured to dynamically set the reference voltage. For example, when there is a voltage ripple at the input, the reference voltage can be set to be near the peak end of the voltage ripple for boost converters, or near the trough end for Buck converters. In some aspects of the disclosure, the voltage reference setter 206 includes both a charge path and a discharge path to dynamically set the reference voltage at a portion of the voltage ripple or add/subtract a portion of a ripple magnitude to/from the reference voltage. In some aspects of the disclosure, the voltage feedforward component is added, at the adder 220, to the input or the output of the PID controller 216 to drive the PWM driver 224. In general, a voltage reference setter 206, scales the input voltage to a level appropriate for control. In some aspects of the disclosure, the voltage reference setter 206 can be, for example, a voltage sampler or a voltage sensor.

In some aspects of the disclosure, the voltage reference setter 206 is electrically connected to the PID controller 216 and the feedforward controller 218. According to certain aspects of the disclosure, the voltage reference setter 206 is also electrically connected to the voltage source 208. In an aspect, the voltage feedforward component is tuned to cancel out, oppose, or otherwise reduce a voltage ripple frequency by adding, at the adder 220,

$${G}_{dvg} ( s ) {v}_{g} ( s ) , \qquad ( 1 )$$

where v_{g} is the supply voltage ripple and

$${G}_{dvg} ( s ) = {G}_{dv} ( s ) {G}_{vs} ( s ) + \frac{( - {G}_{vs} ( s ) )}{{G}_{vd} ( s )} ( 1 + {T}_{eq} ( s ) ) , \qquad ( 2 )$$

G_{dv} is the PID transfer function, and Gᵥₛ(s) is the open-loop voltage ripple divided by the voltage ripple present on the voltage source 208. Teq is defined herein at equation (3).

The voltage source 208 of the power distribution system 200 supplies electrical power to the load 212. In some aspects of the disclosure, the voltage source 208 supplies input voltage Vg (FIG. 3). In certain instances, the voltage source 208 or the busbar 204 presents a voltage including a voltage ripple to downstream loads. In some aspects of the disclosure, the voltage source 208 can include one or more batteries. In some aspects of the disclosure, the input voltage Vg produced by the voltage source 208 is provided as input to the boost converter 202. In some aspects of the disclosure, the voltage source 208 or busbar 204 can not tolerate a current ripple coming from the load 212.

The load current sampler 210 of the power distribution system 200 is configured to force all the load current ripple at a set frequency onto the capacitor 310 (FIG. 3) of the boost converter 202 based at least in part on a current feedforward component received from the feedforward controller 218. In general, the load current sampler 210 is a device that measures, senses, estimates, or determines an electrical current flowing through a conductor, and can report that respective current to another component of the power distribution system 200. In some embodiments, the load current sampler 210 can estimate the load current onto the capacitor 310 (FIG. 3). Accordingly, non-limiting aspects of the disclosure can be included wherein the load current sampler 210 can act as an “ammeter” that can sample or estimate the current at a specific point in a circuit without significantly disrupting the flow of electricity. In general, the load current sampler 210 can be used in power systems to monitor current levels precisely. In some aspects of the disclosure, the load current sampler 210 is electrically connected and downstream of the boost converter 202. In some aspects of the disclosure, the load current sampler 210 is electrically connected to the feedforward controller 218.

The load 212 can be any of various electrical devices that consume electrical power, such as motors that driver compressors, pumps, fans, propulsion systems, and the like. In some aspects of the disclosure, the load 212 does not tolerate a voltage ripple coming from the voltage source 208. In some circumstances, the load 212 can produce a current ripple, which cannot be tolerated by the voltage source 208. In some aspects of the disclosure, the load 212 receives electrical power from the voltage source 208 via the boost converter 202.

In some aspects of the disclosure, the power distribution system 200 includes continuous-time controller for continuous-time control. In other aspects of the disclosure, the power distribution system 200 includes discrete-time controller for discrete-time control. In some aspects of the disclosure, the power distribution system 200 uses one of the two control strategies, continuous-time control and discrete-time control. In general, continuous-time control refers to monitoring and reacting to changes in a system continuously, at every moment in time, capturing all fluctuations without any sampling intervals. Discrete-time control refers to analyzing and adjusting a process at specific, regularly spaced points in time. For any continuous-time system, there is at least one equivalent discrete-=time system that approximates the continuous-time system, which can be to an arbitrary accuracy.

The voltage divider 214 can be a voltage sensor, for example, for the power distribution system 200, and can be configured to measure, sense, determine, or estimate the output voltage Vout (FIG. 3). In some aspects of the disclosure, the voltage divider 214 provides the measured output to the PID controller 216 via a feedback path. In yet certain aspects of the disclosure, the voltage divider 214 is electrically connected to the load 212.

The PID controller 216 of the power distribution system 200 is configured to regulate the output voltage to match the reference voltage by modulating the first PWM signal 312 (FIG. 3) at the PWM driver 224. In some aspects of the disclosure, stability of the PID controller 216 is determined by analyzing an open loop transfer function defined by

$${T}_{eq} ( s ) = {\sum }_{k ∈ ℤ} {G}_{dv} ( s + j 2 π {f}_{PWM} k ) {G}_{vd} ( s + j 2 π {f}_{PWM} k ) \qquad ( 3 )$$

for the Nyquist Stability Criterion. In some aspects of the disclosure, the PID controller 216 is electrically connected to the adder 220. According to certain aspects of the disclosure, the PID controller 216 receives an input from the voltage reference setter 206 and an input from the voltage divider 214. In a non-limiting example, the PID controller 216 receives an input from the feedforward controller 218. In another non-limiting example, the PID controller 216 can have some components of its control law (such as proportional, integral, or differential gain) set to zero. In another non-limiting example, the PID controller 216 can be replaced by another continuous-time or discrete-time controller.

As referenced previously, the feedforward controller 218 is configured to apply a feedforward component to direct the load current ripple into the capacitor 310 of the boost converter 202 rather than into the voltage source 208. In some aspects of the disclosure, the current feedforward component can refer to a current feedforward term. In an aspect, the current feedforward component is tuned by adding, at the adder 220,

$${G}_{d i} ( s ) {i}_{c} ( s ) , \qquad ( 4 )$$

where i_{c} is an estimated load current ripple measured or estimated by the load current sampler 210, and

$${G}_{di} ( s ) = {G}_{dv} ( s ) {G}_{vs} ( s ) + \frac{( {G}_{vi} ( s ) - {G}_{vs} ( s ) )}{{G}_{vd} ( s )} ( 1 + {T}_{eq} ( s ) ) , \qquad ( 5 )$$

G_{dv} is a PID transfer function and Gᵥₛ(s) is an open-loop voltage ripple divided by the load current ripple. In a non-limiting example, the gain can be split into or among two components, processing the current measurement trough G_{dv}(s) compensator before adding to the PID controller 216 input, which as the G_{dv}(s) compensation and approximating

$$\frac{( {G}_{vi} ( s ) - {G}_{vs} ( s ) )}{{G}_{vd} ( s )} ( 1 + {T}_{eq} ( s ) ) .$$

In another non-limiting example, an ideal value for G_{di}(s) can be approximated by finite components, and any approximation can be made at one or more frequencies that are most important to attenuate defined by those finite components. In non-limiting examples, a ripple current is contemplated at 20 kHz and related harmonics (e.g., 40 kHz, 60 kHz, etc.), while other frequencies are contemplated.

The adder 220 of the power distribution system 200 is configured to add the feedforward components, signals, communications, or the like, including, but not limited to, the voltage feedforward component and the current feedforward component, to a feedback component, signal, communication, value, or the like. In some aspects of the disclosure, the feedback component can refer to a feedback term. In some aspects of the disclosure, the feedback component, signal, term, or value can be representative of the difference between the reference voltage and the output voltage passed through a compensator (e.g., G_{dv}). In a non-limiting example, the feedback component can be the difference between the reference voltage and the output voltage, as well as adding a compensated current term, which can pass through a compensator (e.g., G_{dv}). In some aspects of the disclosure, the adder 220 is electrically connected to the PWM driver 224. According to certain aspects of the disclosure, the adder 220 is configured to add the voltage feedforward component with an input or an output of the PID controller 216 to drive the PWM driver 224.

The current limiter 222 of the power distribution system 200 is configured to apply a soft limit (or a hard limit in some configurations) on the inductor current during startup. For example, if the inductor current is above threshold, an op amp of the current limiter can trip and force the duty cycle to zero, which leads to discharging the inductor current. In a non-limiting example, the current limiter 222 can detect or protect against short-circuit conditions. A hard limit can ensure a limit will not be exceeded and is beneficial in promoting stability. A soft limit can include where the PWM signal acts on the circuit such that the inductor current tends to reduce after reaching the soft limit, while further limitations such as response time can ensure that the current does not exceed the threshold.

The PWM driver 224 is configured to generate the first PWM signal 312 (FIG. 3) and the second PWM signal 314 (FIG. 3). In some aspects of the disclosure, the first PWM signal 312 turns the first transistor 304 (FIG. 3) on to conduct current through the inductor 302. In yet certain aspects of the disclosure, the second transistor 306 (FIG. 3) is turned on, based on the second PWM signal 314, to deliver the current, conducted and accumulated by the inductor 302, to the load 212 downstream from the inductor 302. According to some aspects of the disclosure, the second PWM signal 314 is a complement of the first PWM signal 312, including deadtime and shoot-through protection. In a non-limiting example, buck converters can be utilized.

The power distribution system 200 can further include an offset adder (not shown) that is configured to apply an offset feedforward component or offset the reference voltage passed to the PID controller 216, as explained herein. In some aspects of the disclosure, the offset component can refer to an offset feedforward term, signal, communication, or value. Applying the offset component can include adding or subtracting an offset voltage to a sensed input voltage used to set the reference voltage. In some aspects of the disclosure, the offset voltage is added to provide greater control (or finer control) authority to the power distribution system 200, or to maintain a high level of control amid an input voltage ripple.

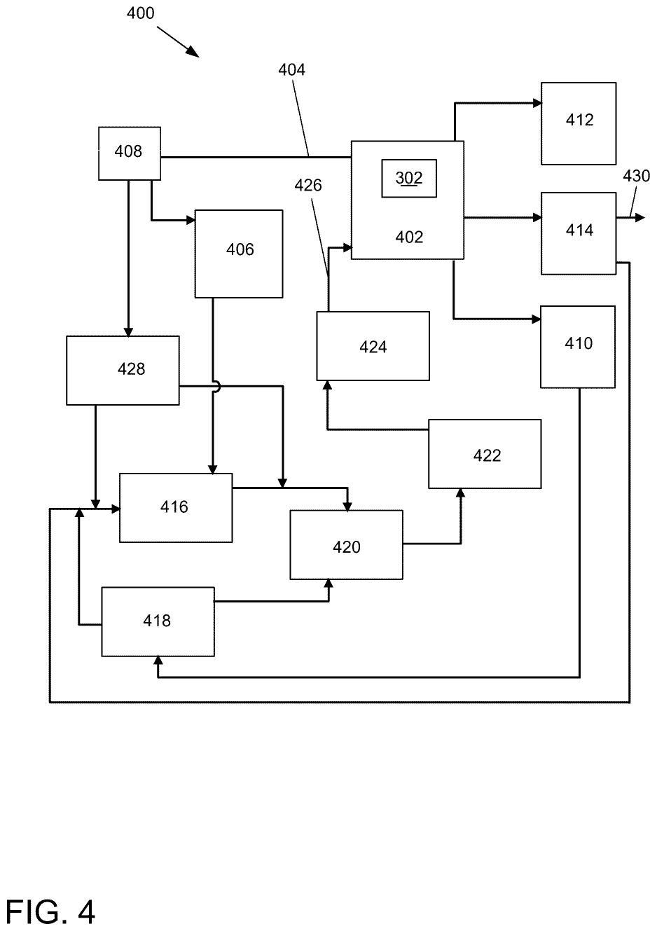

FIG. 4 is another circuit illustrating a power distribution system 400, according to various aspects of the disclosure, which can include or be integrated with the power distribution system 100 of FIG. 1, for example. The power distribution system 400 can be substantially similar to the power distribution system 200 of FIG. 2. As such, similar numerals are utilized with similar components, with the numeral increased by a value of 200. The discussion will be primarily limited to the differences between the two.

The power distribution system 400 includes a power converter 402 provided as a buck converter, a busbar 404, a voltage reference setter 406, a voltage source 408, a load current sampler 410 (i.e., current sampler), a load 412, a voltage divider 414, a PID controller 416, a current cancellation controller 418, an adder 420, a current limiter 422, a PWM driver 424 providing a pulse width modulation (PWM) 426 to the power converter 402, and a voltage ripple cancellation controller 428. In some aspects of the disclosure, the power converter 402 is electrically connected to the voltage source 408 via the busbar 404, and a voltage output 430 provided from the voltage divider 414. The power distribution system 400 can utilize a buck converter. In general, the buck converter is a step-down converter that converts a relatively higher or larger first input voltage to a relatively lower or smaller second output voltage.

The PID controller 416 couples to the adder 420 for providing a signal to the adder 420. The adder 420 is configured to add the feedforward components, signals, communications, or the like, including, but not limited to, the voltage feedforward component and the current feedforward component, to a feedback component, signal, communication, value, or the like.

The voltage ripple cancellation controller 428 is configured to receive a signal or a voltage from the voltage source 408. The voltage ripple cancellation controller 428 can measure the voltage supplied from the voltage source 408 and can be configured to operate, control, or instruct one or more other components of the power distribution system 400 in order to mitigate voltage ripples. For example, the voltage ripple cancellation controller 428 can provide a voltage or signal to the PID controller 416 indicative of the voltage or ripple required to mitigate the voltage ripple on the power distribution system 400. The PID controller 416 can then couple to the adder 420, operably, electrically, or both, in order to control the voltage or any ripple at the adder 420, to mitigate the voltage ripple. In another example, the voltage ripple cancellation controller 428 can provide a voltage or signal directly to the adder 420 to mitigate the voltage ripple. A voltage feedforward component can be added at the adder 220 to the input or the output of the PID controller 216, which can scale the input voltage to a level appropriate for control or mitigation of the voltage ripple.

In another non-limiting example, a current ripple cancellation can be achieved through communication from the voltage ripple cancellation controller 428 with outputs to both the PID controller 416 and the adder 420. A first output is provided to the PID controller 416 while a second output is provided to the output from the PID controller 416 prior to the adder 420. Utilizing two outputs can provide consistent mitigation of the voltage ripple.

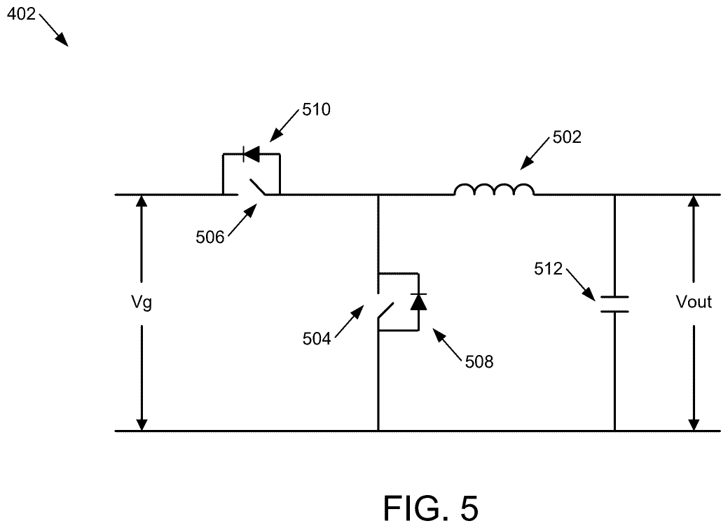

Referring to FIG. 5, the power converter 402 is depicted for the buck converter with a first transistor 506, a second transistor 504, a first diode 510, a second diode 508, a capacitor 512, or a combination thereof, and includes an inductor 502. In some aspects of the disclosure, the first transistor 504 is turned on or otherwise controllably operated, based on a first PWM signal 314, which can be generated by the PWM driver 424 of the power distribution system 400 of FIG. 4, for example, to accumulate by, or conduct current through, the inductor 502. In some aspects of the disclosure, the first or second transistors 504, 506 can be turned on or otherwise controllably operated, based on a PWM signal, to limit the current, accumulated by, or conducted through, the inductor 502, such as to the load 412 (FIG. 4), downstream from the inductor 502. In some aspects of the disclosure, the PWM signal can include deadtime and shoot-through protection. A capacitor 512 is configured to absorb, balance, even, or otherwise reduce a load current ripple produced by the conduction of current to the load 412 (FIG. 4) or inductor current.

In some aspects of the disclosure, the buck converter 402 is configured to buck an input voltage Vg supplied by the voltage source 408 (FIG. 4) to a different, higher or larger voltage. In some aspects of the disclosure, the bucking of the input voltage Vg at the buck converter 402 is kept at minimum to minimize the current ripple introduced back onto the busbar 404 (FIG. 4) or the voltage source 408 (FIG. 4).

Referring again to FIG. 4, the voltage reference setter 406 is configured to apply a voltage feedforward component to accommodate, represent, or account for a voltage ripple or a steady state voltage generated by the voltage source 408. In some aspects of the disclosure, the voltage reference setter 206 is configured to dynamically set the reference voltage. For example, when there is a voltage ripple at the input, the reference voltage can be set to be near the trough end for the buck converter 402. In some aspects of the disclosure, the voltage feedforward component is added, at the adder 420, to the input or the output of the PID controller 416 to drive the PWM driver 424. In general, a voltage reference setter 406, scales the input voltage to a level appropriate for control. In some aspects of the disclosure, the voltage reference setter 406 can be, for example, a voltage sampler or a voltage sensor. The PID controller 416 is configured to regulate the output voltage to match the reference voltage by modulating the PWM signal. According to certain aspects of the disclosure, the PID controller 416 receives an input from the voltage ripple cancellation controller 428.

The adder 420 is configured to add feedforward components, signals, communications, or the like, including, but not limited to, the voltage feedforward component and the current feedforward component, to a feedback component, signal, communication, value, or the like. In some aspects of the disclosure, the feedback component can refer to a feedback term. In some aspects of the disclosure, the feedback component, signal, term, or value can be representative of the difference between the reference voltage and the output voltage passed through a compensator (e.g., G_{dv}).

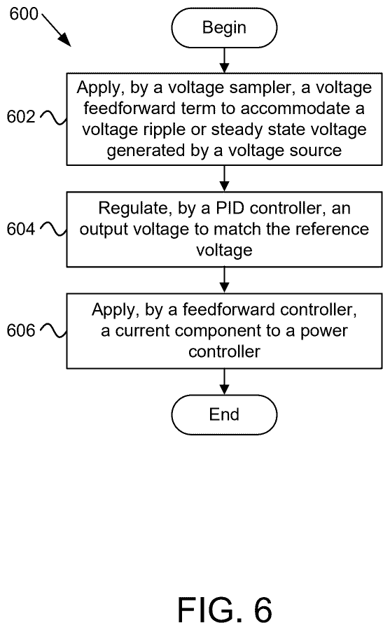

FIG. 6 is a schematic flow chart diagram illustrating an example of a method 600 performed by the power conditioning unit 104 (FIG. 1). The method 600 includes (block 602) applying, such as by the voltage reference setter 206, 406 (FIGS. 2, 4), a voltage feedforward term to accommodate, represent, or account for a voltage ripple or a steady state voltage generated by the voltage source 208, 408 (FIGS. 2, 4). The method 600 additionally includes (block 604) applying, by the feedforward controller 218, 418 (FIGS. 2, 4), a current feedforward component to the boost converter 202 (FIG. 2) or the power converter 402 (FIG. 4), where the current feedforward component counteracts, opposes, reduces, or otherwise accommodates a load current ripple at the load 212, 412 (FIGS. 2, 4) and absorbed, or otherwise experienced by the capacitor 310, 512 (FIGS. 3, 5) of the boost converter 202 or the power converter 402. The method 600 further includes (block 606) regulating, by the proportional-integral-derivative (“PID”) controller 216, 416 (FIGS. 2, 4), an output voltage to match the reference voltage by modulating a first pulse width modulation (“PWM”) signal.

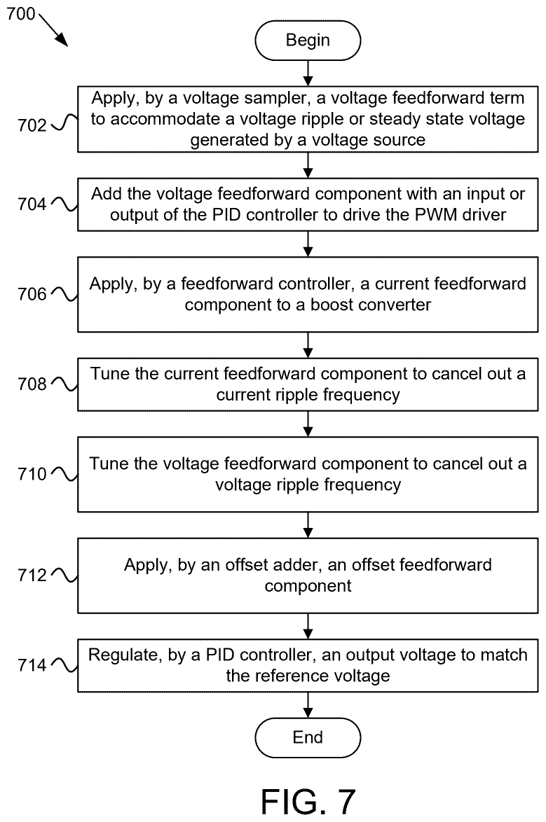

FIG. 7 is a schematic flow chart diagram illustrating another example of a method 700 that can be performed by the power conditioning unit 104 (FIG. 1), for example. The method 700 includes (block 702) applying, by the voltage reference setter 206, 406 (FIG. 2, 4), a voltage feedforward term to accommodate, represent, or account for a voltage ripple or a steady state voltage generated by the voltage source 208, 408 (FIG. 2, 4). In some aspects of the disclosure, applying the voltage feedforward component comprises sampling, sensing, measuring, determining, or estimating an input voltage to dynamically set the reference voltage. In some aspects of the disclosure, the voltage reference setter 206, 406 comprises both a charge path and a discharge path to dynamically set the reference voltage at a portion of the voltage ripple or add a portion of a ripple magnitude to the reference voltage. In a non-limiting example, the charge and discharge paths can be realized in a virtual environment, such as a software system.

The method 700 additionally includes (block 704) adding, at the adder 220, 420 (FIGS. 2, 4), the voltage feedforward component with an input or an output of the PID controller 216, 416 (FIGS. 2, 4) to drive the PWM driver 224, 424 (FIGS. 2, 4). The method 700 also includes (block 706) applying, by the feedforward controller 218, 418 (FIGS. 2, 4), a current feedforward component to the boost converter 202 (FIG. 2) or the power converter 402 (FIG. 4), the current feedforward component counteracts a load current ripple produced by the load 212, 412 (FIGS. 2, 4) and absorbed by the capacitor 310, 512 (FIGS. 3, 5) of the boost converter 202 or the power converter 402. The method 700 further includes (block 708) tuning the current feedforward component to cancel out, oppose, or otherwise reduce a current ripple frequency. In some aspects of the disclosure, tuning the current feedforward component at block 508 comprises adding, at the adder 220, 420,

$${G}_{d i} ( s ) {i}_{c} ( s ) , \qquad ( 5 )$$

wherein i_{c} is a load current ripple and the ideal

$${G}_{d i} ( s ) = {G}_{d v} ( s ) {G}_{vs} ( s ) + \frac{( {G}_{v i} ( s ) - {G}_{v s} ( s ) )}{{G}_{v d} ( s )} ( 1 + {T}_{e q} ( s ) ) , \qquad ( 6 )$$

wherein G_{dv} is a PID transfer function and Gᵥₛ(s) is an open-loop voltage ripple divided by the load current ripple. In a non-limiting example, the realized G_{di}(s) can approximate the ideal G_{di}(s) at equation (6) at only certain or specific frequencies.

The method 700 additionally includes (block 710) tuning the voltage feedforward component to cancel out, oppose, or otherwise reduce a voltage ripple frequency. In some aspects of the disclosure, tuning the voltage feedforward component comprises adding, at the adder 220, 420,

$${G}_{d v g} ( s ) {v}_{g} ( s ) , \qquad ( 7 )$$

wherein v_{g} is the load current ripple and the ideal

$${G}_{d v g} ( s ) = {G}_{d v} ( s ) {G}_{v s} ( s ) + \frac{( - {G}_{v s} ( s ) )}{{G}_{v d} ( s )} ( 1 + {T}_{e q} ( s ) ) , \qquad ( 8 )$$

wherein G_{dv} is the PID transfer function and Gᵥₛ(s) is the open-loop voltage ripple divided by the voltage ripple generated by the voltage source 208, 408.

The method 700 also includes (block 712) applying, by an offset adder, an offset feedforward component. In some aspects of the disclosure, applying the offset feedforward component comprises adding an offset voltage to a sensed input voltage. In some embodiments, the realized G_{dvg}(s) can approximate the ideal G_{dvg}(s) at certain or specific values of s. The method 700 further includes (block 714) regulating or otherwise controlling an output voltage to match the reference voltage by modulating the first PWM signal. In this sense, the regulating or otherwise controlling the output voltage can be performed by the PID controller 216, 416. In some aspects of the disclosure, the stability of the PID controller 216 is determined by analyzing an open loop transfer function defined by

$${T}_{e q} ( s ) = {\sum }_{k ∈ ℤ} {G}_{d v} ( s + j 2 π {f}_{P W M} k ) {G}_{v d} ( s + j 2 π {f}_{P W M} k ) \qquad ( 9 )$$

### by the Nyquist Stability Criterion.

Many of the functional units described in this specification have been labeled as modules, controllers, drivers, etc., in order to more particularly emphasize their implementation independence. For example, a module (which, as used in the following paragraphs includes a controller, a driver, or other electronic control component) can be implemented as a hardware circuit comprising custom VLSI circuits or gate arrays, off-the-shelf semiconductors such as logic chips, transistors, or other discrete components. A module can also be implemented in programmable hardware devices such as field programmable gate arrays, programmable array logic, programmable logic devices or the like.

Modules can also be implemented in code or software for execution by various types of processors. An identified module of code can, for instance, comprise one or more physical or logical blocks of executable code which can, for instance, be organized as an object, procedure, or function. Nevertheless, the executables of an identified module need not be physically located together, but can comprise disparate instructions stored in different locations which, when joined logically together, comprise the module and achieve the stated purpose for the module.

Indeed, a module of code can be a single instruction, or many instructions, and can even be distributed over several different code segments, among different programs, and across several memory devices. Similarly, operational data can be identified and illustrated herein within modules, and can be embodied in any suitable form and organized within any suitable type of data structure. The operational data can be collected as a single data set, or can be distributed over different locations including over different computer readable storage devices. Where a module or portions of a module are implemented in software, the software portions are stored on one or more computer readable storage devices.

Any combination of one or more computer readable medium can be utilized. The computer readable medium can be a computer readable storage medium. The computer readable storage medium can be a storage device storing the code. The storage device can be, for example, but not limited to, an electronic, magnetic, optical, electromagnetic, infrared, holographic, micromechanical, or semiconductor system, apparatus, or device, or any suitable combination of the foregoing.

More specific examples (a non-exhaustive list) of the storage device would include the following: an electrical connection having one or more wires, a portable computer diskette, a hard disk, a random access memory (RAM), a read-only memory (ROM), an erasable programmable read-only memory (EPROM or Flash memory), a portable compact disc read-only memory (CD-ROM), an optical storage device, a magnetic storage device, or any suitable combination of the foregoing. In the context of this document, a computer readable storage medium can be any tangible medium that can contain, or store a program for use by or in connection with an instruction execution system, apparatus, or device.

Code for carrying out operations for examples can be written in any combination of one or more programming languages including an object oriented programming language such as Python, Ruby, Java, Smalltalk, C++, or the like, and conventional procedural programming languages, such as the “C” programming language, or the like, or machine languages such as assembly languages. The code can execute entirely on the user's computer, partly on the user's computer, as a stand-alone software package, partly on the user's computer and partly on a remote computer or entirely on the remote computer or server. In the latter scenario, the remote computer can be connected to the user's computer through any type of network, including a local area network (LAN) or a wide area network (WAN), or the connection can be made to an external computer (for example, through the Internet using an Internet Service Provider).

The described features, structures, or characteristics of the examples can be combined in any suitable manner. In the above description, numerous specific details are provided, such as examples of programming, software modules, user selections, network transactions, database queries, database structures, hardware modules, hardware circuits, hardware chips, etc., to provide a thorough understanding of examples. One skilled in the relevant art will recognize, however, that examples can be practiced without one or more of the specific details, or with other methods, components, materials, and so forth. In other instances, well-known structures, materials, or operations are not shown or described in detail to avoid obscuring aspects of an example.

Aspects of the examples are described above with reference to schematic flowchart diagrams or schematic block diagrams of methods, apparatuses, systems, and program products according to examples. It will be understood that each block of the schematic flowchart diagrams or schematic block diagrams, and combinations of blocks in the schematic flowchart diagrams or schematic block diagrams, can be implemented by code. These code can be provided to a processor of a general purpose computer, special purpose computer, or other programmable data processing apparatus to produce a machine, such that the instructions, which execute via the processor of the computer or other programmable data processing apparatus, create means for implementing the functions/acts specified in the schematic flowchart diagrams or schematic block diagrams block or blocks.

The code can also be stored in a storage device that can direct a computer, other programmable data processing apparatus, or other devices to function in a particular manner, such that the instructions stored in the storage device produce an article of manufacture including instructions which implement the function/act specified in the schematic flowchart diagrams or schematic block diagrams block or blocks.

The code can also be loaded onto a computer, other programmable data processing apparatus, or other devices to cause a series of operational steps to be performed on the computer, other programmable apparatus or other devices to produce a computer implemented process such that the code which execute on the computer or other programmable apparatus provide processes for implementing the functions/acts specified in the flowchart or block diagram block or blocks.

The schematic flowchart diagrams or schematic block diagrams in the figures illustrate the architecture, functionality, and operation of possible implementations of apparatuses, systems, methods and program products according to various examples. In this regard, each block in the schematic flowchart diagrams or schematic block diagrams can represent a module, segment, or portion of code, which comprises one or more executable instructions of the code for implementing the specified logical function(s).

The present disclosure can be embodied in other specific forms without departing from its spirit or essential characteristics. The described aspects of the disclosure are to be considered in all respects only as illustrative and not restrictive. The scope of the present disclosure is, therefore, indicated by the appended claims rather than by the foregoing description. All changes which come within the meaning and range of equivalency of the claims are to be embraced within their scope.

To the extent not already described, the different features and structures of the various embodiments can be used in combination, or in substitution with each other as desired. That one feature is not illustrated in all of the embodiments is not meant to be construed that it cannot be so illustrated, but is done for brevity of description. Thus, the various features of the different embodiments can be mixed and matched as desired to form new embodiments, whether or not the new embodiments are expressly described. All combinations or permutations of features described herein are covered by this disclosure.

This written description uses examples to disclose the present disclosure, including the best mode, and also to enable any person skilled in the art to practice the disclosure, including making and using any devices or systems and performing any incorporated methods. The patentable scope of the disclosure is defined by the claims, and can include other examples that occur to those skilled in the art. Such other examples are intended to be within the scope of the claims if they include structural elements that do not differ from the literal language of the claims, or if they include equivalent structural elements with insubstantial differences from the literal languages of the claims.

Further aspects are provided by the subject matter of the following clauses:

A power conditioning unit comprising: a boost converter comprising an inductor, a first transistor, a second transistor, and a capacitor, wherein: the first transistor is turned on, based on a first pulse width modulation (“PWM”) signal generated by a PWM driver, to accumulate a current through the inductor; the second transistor is turned on, based on a second PWM signal, to decrease the current, accumulated by the inductor, onto a load downstream from the inductor; and the capacitor is configured to operably absorb a load current ripple produced by the load; a voltage reference setter configured to apply a voltage feedforward component to accommodate a voltage ripple or a steady state voltage generated by a voltage source; a feedforward controller configured to apply a current feedforward component such that the capacitor of the boost converter operably absorbs the load current ripple; and a proportional-integral-derivative (“PID”) controller configured to regulate output voltage to match a reference voltage by modulating the first PWM signal.

The power conditioning unit of any preceding clause, wherein applying the voltage feedforward component comprises dynamically or continuously sampling an input voltage to dynamically or continuously set the reference voltage.

The power conditioning unit of any preceding clause, wherein the voltage reference setter comprises both a charge path and a discharge path to dynamically set the reference voltage at a portion of the voltage ripple, or add or subtract a portion of a ripple magnitude to or from the reference voltage.

The power conditioning unit of any preceding clause, further comprising an offset adder configured to apply an offset feedforward component, wherein applying the offset feedforward component comprises adding an offset voltage to a sensed input voltage.

The power conditioning unit of any preceding clause, wherein the offset voltage can be positive or negative.

The power conditioning unit of any preceding clause, wherein stability of the PID controller is determined by analyzing an open loop transfer function defined by: T_{eq}(s)= [symbol] G_{dv}(s+j2πf_{PWM}k)G_{vd}(s+j2πf_{PWM}k) against a Nyquist Stability Criterion.

The power conditioning unit of any preceding clause, further comprising an adder configured to add a transient cancellation component with an input or an output of the PID controller to drive the PWM driver.

The power conditioning unit of any preceding clause, wherein: the transient cancellation component is a current feedforward component that is tuned to cancel out a current ripple frequency by adding, at the adder, G_{di}(s)i_{c}(s); i_{c} is the load current ripple and

$${G}_{d i} ( s ) = {G}_{d v} ( s ) {G}_{v s} ( s ) + \frac{( {G}_{v i} ( s ) - {G}_{v s} ( s ) )}{{G}_{v d} ( s )} ( 1 + {T}_{e q} ( s ) ) ;$$

and G_{dv} is a PID transfer function and Gᵥₛ(s) is an open-loop voltage ripple divided by the load current ripple.

The power conditioning unit of any preceding clause, wherein adding G_{di}(s) can be realized at an input or an output to or from the PID controller.

The power conditioning unit of any preceding clause, wherein a realized G_{di}(s) more closely approximates an ideal i(s) at frequencies associated with the voltage ripple.

The power conditioning unit of any preceding clause, wherein: the transient cancellation component is a voltage feedforward component is tuned to cancel out the voltage ripple by adding, at the adder, G_{dvg}(s)v_{g}(s); v_{g} is a supply voltage ripple and

$${G}_{d v g} ( s ) = {G}_{d v} ( s ) {G}_{v s} ( s ) + \frac{( - {G}_{v s} ( s ) )}{{G}_{v d} ( s )} ( 1 + {T}_{e q} ( s ) ) ;$$

and G_{dv} is a PID transfer function and Gᵥₛ(s) is an open-loop voltage ripple divided by the voltage ripple generated by the voltage source.

The power conditioning unit of any preceding clause, wherein adding the G_{dv}(s) can be realized at an input or an output to or from the PID controller.

The power conditioning unit of any preceding clause, wherein a realized G_{dv}(s) more closely approximates an ideal G_{dv}(s) at frequencies associated with the voltage ripple.

A method of conditioning electrical power, the method comprising: applying, by a voltage reference setter, a voltage feedforward component to accommodate a voltage ripple or a steady state voltage generated by a voltage source; applying, by a feedforward controller, a current feedforward component to a boost converter, wherein the current feedforward component is configured to shunt a load current ripple produced by a load away from a busbar; and regulating, by a proportional-integral-derivative (“PID”) controller, an output voltage to match a reference voltage by modulating a first pulse width modulation (“PWM”) signal.

The method of any preceding clause, wherein applying the voltage feedforward component comprises dynamically sampling an input voltage to dynamically set the reference voltage.

The method of any preceding clause, wherein the voltage reference setter comprises both a charge path and a discharge path to dynamically set the reference voltage at a portion of the voltage ripple or add or subtract a portion of a ripple magnitude to or from the reference voltage.

The method of any preceding clause, further comprising applying, by an offset adder, an offset feedforward component, wherein applying the offset feedforward component comprises adding an offset voltage to a sensed input voltage.

The method of any preceding clause, wherein the offset voltage can be positive or negative.

The method of any preceding clause, wherein stability of the PID controller is determined by analyzing an open loop transfer function defined by: T_{eq}(s)= [symbol] G_{dv}(s+j2πf_{PWM}k)G_{vd}(s+j2πf_{PWM}k) against a Nyquist Stability Criterion.

The method of any preceding clause, further comprising adding, at an adder, a transient cancellation component with an input or an output of the PID controller to drive a PWM driver.

The method of any preceding clause, further comprising tuning the transient cancellation component to cancel out a current ripple frequency, wherein: tuning the current feedforward component comprises adding, at the adder, G_{di}(s) i_{c}(s); i_{c} is a load current ripple and

$${G}_{d i} ( s ) = {G}_{d v} ( s ) {G}_{v s} ( s ) + \frac{( {G}_{v i} ( s ) - {G}_{v s} ( s ) )}{{G}_{v d} ( s )} ( 1 + {T}_{e q} ( s ) ) ;$$

and G_{dv} is a PID transfer function and Gᵥₛ(s) is an open-loop voltage ripple divided by the load current ripple.

The method of any preceding clause, wherein adding G_{di}(s) can be realized at an input or an output to or from the PID controller.

The method of any preceding clause, wherein a realized G_{di}(s) more closely approximates an ideal i(s) at frequencies associated with the voltage ripple.

The method of any preceding clause, further comprising tuning the transient cancellation component to cancel out a voltage ripple frequency, wherein: tuning the voltage feedforward component comprises adding, at the adder, G_{dvg}(s)v_{g}(s); v_{g} is a load current ripple and

$${G}_{d v g} ( s ) = {G}_{d v} ( s ) {G}_{v s} ( s ) + \frac{( - {G}_{v s} ( s ) )}{{G}_{v d} ( s )} ( 1 + {T}_{e q} ( s ) ) ;$$

and G_{dv} is a PID transfer function and Gᵥₛ(s) is an open-loop voltage ripple divided by the voltage ripple generated by the voltage source.

The method of any preceding clause, wherein adding the G_{dv}(s) can be realized at an input or an output to or from the PID controller.

The method of any preceding clause, wherein a realized G_{di}(s) more closely approximates an ideal i(s) at frequencies associated with the voltage ripple.

What is claimed is:

1. A power conditioning unit comprising:
a boost converter comprising an inductor, a first transistor, a second transistor, and a capacitor, wherein:
the first transistor is turned on, based on a first pulse width modulation (“PWM”) signal generated by a PWM driver, to accumulate a current through the inductor;
the second transistor is turned on, based on a second PWM signal, to decrease the current, accumulated by the inductor, onto a load downstream from the inductor; and
the capacitor is configured to operably absorb a load current ripple produced by the load;
a voltage reference setter configured to apply a voltage feedforward component to accommodate a voltage ripple or a steady state voltage generated by a voltage source;
a feedforward controller configured to apply a current feedforward component such that the capacitor of the boost converter operably absorbs the load current ripple; and
a proportional-integral-derivative (“PID”) controller configured to regulate output voltage to match a reference voltage by modulating the first PWM signal.

2. The power conditioning unit of claim 1, wherein applying the voltage feedforward component comprises dynamically or continuously sampling an input voltage to dynamically or continuously set the reference voltage.

3. The power conditioning unit of claim 2, wherein the voltage reference setter comprises both a charge path and a discharge path to dynamically set the reference voltage at a portion of the voltage ripple, or add or subtract a portion of a ripple magnitude to or from the reference voltage.

4. The power conditioning unit of claim 2, further comprising an offset adder configured to apply an offset feedforward component, wherein applying the offset feedforward component comprises adding an offset voltage to a sensed input voltage.

5. The power conditioning unit of claim 4, wherein the offset voltage can be positive or negative.

6. The power conditioning unit of claim 1, wherein stability of the PID controller is determined by analyzing an open loop transfer function defined by:
$${T}_{e q} ( s ) = {\sum }_{k ∈ ℤ} {G}_{d v} ( s + j 2 π {f}_{P W M} k ) {G}_{v d} ( s + j 2 π {f}_{P W M} k )$$
against a Nyquist Stability Criterion.

7. The power conditioning unit of claim 1, further comprising an adder configured to add a transient cancellation component with an input or an output of the PID controller to drive the PWM driver.

8. The power conditioning unit of claim 7, wherein:
the transient cancellation component is a current feedforward component that is tuned to cancel out a current ripple frequency by adding, at the adder, G_{di}(s)i_{c}(s);
i_{c} is the load current ripple and
$${G}_{d i} ( s ) = {G}_{d v} ( s ) {G}_{v s} ( s ) + \frac{( {G}_{v i} ( s ) - {G}_{v s} ( s ) )}{{G}_{v d} ( s )} ( 1 + {T}_{e q} ( s ) ) ;$$
and
G_{dv} is a PID transfer function and Gᵥₛ(s) is an open-loop voltage ripple divided by the load current ripple.

9. The power conditioning unit of claim 7, wherein:
the transient cancellation component is a voltage feedforward component is tuned to cancel out the voltage ripple by adding, at the adder, G_{dvg}(s)v_{g}(s);
v_{g} is a supply voltage ripple and
$${G}_{d v g} ( s ) = {G}_{d v} ( s ) {G}_{v s} ( s ) + \frac{( - {G}_{v s} ( s ) )}{{G}_{v d} ( s )} ( 1 + {T}_{e q} ( s ) ) ;$$
and
G_{dv} is a PID transfer function and Gᵥₛ(s) is an open-loop voltage ripple divided by the voltage ripple generated by the voltage source.

10. The power conditioning unit of claim 9, wherein adding the G_{dv}(s) can be realized at an input or an output to or from the PID controller.

11. The power conditioning unit of claim 9, wherein a realized G_{dv}(s) more closely approximates an ideal G_{dv}(s) at frequencies associated with the voltage ripple.

12. A method of conditioning electrical power, the method comprising:
applying, by a voltage reference setter, a voltage feedforward component to accommodate a voltage ripple or a steady state voltage generated by a voltage source;
applying, by a feedforward controller, a current feedforward component to a boost converter, wherein the current feedforward component is configured to shunt a load current ripple produced by a load away from a busbar; and
regulating, by a proportional-integral-derivative (“PID”) controller, an output voltage to match a reference voltage by modulating a first pulse width modulation (“PWM”) signal.

13. The method of claim 12, wherein applying the voltage feedforward component comprises dynamically sampling an input voltage to dynamically set the reference voltage.

14. The method of claim 13, wherein the voltage reference setter comprises both a charge path and a discharge path to dynamically set the reference voltage at a portion of the voltage ripple or add or subtract a portion of a ripple magnitude to or from the reference voltage.

15. The method of claim 13, further comprising applying, by an offset adder, an offset feedforward component, wherein applying the offset feedforward component comprises adding an offset voltage to a sensed input voltage.

16. The method of claim 14, wherein regulating the PID controller is determined by analyzing an open loop transfer function defined by:
$${T}_{e q} ( s ) = {\sum }_{k ∈ ℤ} {G}_{d v} ( s + j 2 π {f}_{P W M} k ) {G}_{v d} ( s + j 2 π {f}_{P W M} k )$$
against a Nyquist Stability Criterion.

17. The method of claim 12, further comprising adding, at an adder, a transient cancellation component with an input or an output of the PID controller to drive a PWM driver.

18. The method of claim 17, further comprising tuning the transient cancellation component to cancel out a current ripple frequency, wherein:
tuning the current feedforward component comprises adding, at the adder, G_{di}(s)i_{c}(s);
i_{c} is a load current ripple and
$${G}_{d i} ( s ) = {G}_{d v} ( s ) {G}_{v s} ( s ) + \frac{( {G}_{v i} ( s ) - {G}_{v s} ( s ) )}{{G}_{v d} ( s )} ( 1 + {T}_{e q} ( s ) ) ;$$
and
G_{dv} is a PID transfer function and Gᵥₛ(s) is an open-loop voltage ripple divided by the load current ripple.

19. The method of claim 18, wherein adding G_{di}(s) can be realized at an input or an output to or from the PID controller.

20. The method of claim 17, further comprising tuning the transient cancellation component to cancel out a voltage ripple frequency, wherein:
tuning the voltage feedforward component comprises adding, at the adder, G_{dvg}(s)v_{g}(s);
v_{g} is a load current ripple and
$${G}_{d v g} ( s ) = {G}_{d v} ( s ) {G}_{v s} ( s ) + \frac{( - {G}_{v s} ( s ) )}{{G}_{v d} ( s )} ( 1 + {T}_{e q} ( s ) ) ;$$
and
G_{dv} is a PID transfer function and Gᵥₛ(s) is an open-loop voltage ripple divided by the voltage ripple generated by the voltage source.
